(19) United States
(12) Patent Application Publication
(10) Pub. No.: US 2022/0127451 A1
(43) Pub. Date: Apr. 28, 2022

(54) FAN UNIT CONTAINING RECYCLED AND RENEWABLE POLYMERIC COMPOSITIONS

(71) Applicant: Dell Products L.P., Round Rock, TX (US)

(72) Inventors: Nicholas D. Abbatiello, Round Rock, TX (US); Xinhua Tian, Shanghai (CN); Chris Helberg, Austin, TX (US)

(73) Assignee: Dell Products L.P., Round Rock, TX (US)

(21) Appl. No.: 17/083,194

(22) Filed: Oct. 28, 2020

(51) Int. Cl. C08L 67/02; H05K 7/20; C09K 19/38

(52) U.S. Cl. CPC C08L 67/02; C08K 7/14; C09K 19/38; H05K 7/20172

(57) ABSTRACT

A polymeric composition and fan unit containing the polymeric composition are described. The polymeric composition can contain 5 wt. % to 30 wt. % of a mechanically recycled polyethylene terephthalate (PET) polymer, 5 wt. % to 80 wt. % of a polybutylene terephthalate (PBT) polymer, wherein the PBT polymer is a reaction product of polymerizing 1,4 butane diol (BDO) with chemically recycled terephthalic acid or is derived from fossil fuel based feed stock, 5 wt. % to 35 wt. % of a filler, and 2 wt. % to 20 wt. % of a non-halogenated flame retardant.

### BACKGROUND OF THE INVENTION

### A. Field of the Invention

The invention relates to polymeric compositions with high recycled and renewable content while having sufficient mechanical strength for use in a fan unit of an electronic device (e.g., desktop computers, laptop or notebook computers, computer servers, etc.

### B. Description of Related Art

Electronic device (e.g., computers and computer servers) fan units are capable of cooling the device and/or parts of the device. Fan units, due to their use in electronic devices and in cooling, have demanding safety and mechanical performance requirements, especially when such fan units are used for computer devices (e.g., desktop or laptops). These requirements have typically been met by using polyester polymers to form the fan blade and housing of the fan unit. However certain commonly used polyesters, such as polyethylene terephthalate (PET), are non-biodegradable and if not recycled can create various environmental problems (e.g., increased landfills, increased use of natural resources and energy, etc.) Thus, efforts have been made to increase recycle content of a fan unit.

A traditional recycling method includes mechanical recycling. Mechanical recycling typically includes collecting used products or debris having the target polymer (e.g., polyester-based plastics), optionally washing the used products or debris, melting the used products or debris into a raw material having the target polymer, and reusing the raw material to produce new articles of manufacture. The mechanical properties (e.g., tensile strength, tensile modulus etc.) of the recycled plastics (e.g. polyester) can decrease due to input of energy during the melting process. In particular, the melting process can lead to polymer chain scissions and lead to weaker polymers. Thus, mechanical properties of a fan unit can decrease, with increasing amounts of mechanically recycled polymer. This can present a significant limit on the amount of recycled material that can be used in electronic device fan units.

### SUMMARY OF THE INVENTION

A discovery has been made that provides a solution to at least one or more of the problems that may be associated with improving the sustainability of a fan unit, such as a computer or server fan unit. In one aspect, the solution can include supplementing the mechanically recycled polymer (e.g., mechanically recycled polyester) in a polymer composition of a fan unit with other recycled components and/or components made from renewable material. This can allow for an increase in the overall recycled and renewable content of a polymeric composition without compromising the mechanical strength of the composition. Therefore, a more sustainable fan unit can be produced without comprising the mechanical durability of the fan unit. In one aspect of the present invention, it was found that a polymeric composition containing particular amounts of mechanically recycled PET polymer, a polybutylene terephthalate (PBT) polymer, a filler, and a flame retardant can provide for fan units having relatively high recycled and renewable content and good mechanical and/or acoustic properties.

One aspect of the present invention is directed to a first polymeric composition. The first polymeric composition can contain a mechanically recycled polyethylene terephthalate (PET) polymer, a polybutylene terephthalate (PBT) polymer, a filler, and a flame retardant. In some aspects, the first polymeric composition can contain 5 wt. % to 40 wt. % of the PET polymer, 5 wt. % to 80 wt. % the PBT polymer, 5 wt. % to 40 wt. % of the filler, and 2 wt. % to 20 wt. % the flame retardant. The mechanically recycled PET, can be at least, in part, obtained by mechanical recycling of PET containing waste. In some aspects, the PBT polymer, can be obtained from a fossil fuel based feed stock. The PBT polymer can be a virgin polymer obtained from a fossil fuel based feed stock. In some other aspects, the PBT polymer can be obtained from 1,4-butanediol (BDO) and terephthalic acid. In some particular aspects, 1,4-BDO can be reacted with terephthalic acid and/or a terephthalic acid derivative to produce the PBT polymer. The terephthalic acid derivative, can be obtained from terephthalic acid. The terephthalic acid used to form the PBT polymer can be obtained by chemical recycling of PET. In some aspects, the PET can be post-consumer waste PET. In some aspects, at least a portion of the 1,4-BDO used to form the PBT can be renewably sourced (e.g., obtained from a bio-renewable source). In some aspects, the bio-renewable source can be tall oil, caster beans, sugar, lignocellulose, or glycerol. The renewably sourced 1,4-BDO can include carbon atoms from the bio-renewable source. In some aspects, the PBT polymer can be a reaction product from polymerizing renewably sourced 1,4-BDO with chemically recycled terephthalic acid (e.g., chemically recycled terephthalic acid obtained from PET). In some aspects, the flame retardant can be a renewably sourced flame retardant. In some particular aspects, the flame retardant can be a non-halogenated flame retardant can be obtained from bio based chemicals. In some aspects, the filler can contain glass fibers, and/or carbon fibers, or a combination thereof. In some aspects, the carbon fibers can be recycled carbon fibers. In some particular aspects, the filler can contain glass fibers. In certain aspects, the first polymeric composition can further contain an additive selected from pigments, plasticizers, antioxidants, UV-stabilizers, heat stabilizers, dye enhancing agents, lubricant, mold release agents, crystal nucleating agents, fluidability-improving agents, antistatic agents, anti-drip agents, and/or compatibilizers, or any combinations thereof. The total recycled and renewable content of the first polymeric composition can be 5 wt. % to 90 wt. %, or 5 wt. % to 60 wt. %. In some particular aspects, the first polymeric composition can contain 5 wt. % to 25 wt. % of the PET polymer, 15 wt. % to 40 wt. % of the PBT polymer, 10 wt. % to 35 wt. % of the filler, the filler containing glass fiber, 5 wt. % to 20 wt. % of the flame retardant, and optionally 0.01 to 3 wt. % of the pigment. In some aspects, the first polymeric composition can have a tensile modulus greater than 5,100 MPa, preferably 10,000 MPa to 12,000 MPa at 23° C., as measured in accordance with ISO 527-2, a tensile strength of at least 70 MPa, preferably 90 MPa to 140 MPa at 23° C. as measured in accordance with ISO 527-2, a heat flexural modulus of greater than 4,500 MPa preferably 7450 MPa to 10000 MPa at 23° C., as measured in accordance with ISO 178, or a UL94 rating of V0 at a thickness 1.5 mm, or any combinations thereof. In some aspects, the first polymeric composition can be comprised in a fan unit for an electronic device. In some aspects, the electronic device can be a computer or a computer server. In some particular aspects, the first polymeric composition can be comprised in a fan blade and/or fan housing of a fan unit of a computer, such as desktop or laptop computer, or a computer server. In some aspects, the at least 90 wt. % of the fan blade, fan housing and/or fan unit can be comprised of the first polymeric composition.

Certain aspects of the present invention are directed to a fan unit. The fan unit can comprise i) a fan blade containing a second polymeric composition and ii) a fan housing containing a third polymeric composition. The second polymeric composition can contain a liquid crystal polymer (LCP) and a filler. In some aspects, the LCP polymer can be obtained from an aromatic monomer and recycled acetic acid and/or recycled acetic anhydride. In some particular aspects, the LCP polymer can be a reaction product of polymerizing the aromatic monomer with the recycled acetic acid and/or recycled acetic anhydride. The LCP polymer at least in part can be a recycled LCP polymer. In some aspects, a portion of the LCP polymer can be virgin polymer. In some aspects, the filler of the second polymeric composition can contain glass fibers, carbon fibers, or a combination thereof. In certain aspects, the carbon fibers can be recycled carbon fibers. In some aspects, the second polymeric composition can contain 65 wt. % to 90 wt. % of the LCP and 5 wt. % to 40 wt. % of the filler. At least 90 wt. % of the fan blade can be comprised of the second polymeric composition. In some aspects, the second polymeric composition can have a tensile modulus greater than 12,000 MPa, preferably 15,000 MPa to 23,500 MPa at 23° C., as measured in accordance with ISO 527-2, a tensile strength of at least 100 MPa, preferably 100 MPa to 150 MPa at 23° C. as measured in accordance with ISO 527-2, a heat flexural modulus greater than 10,000 MPa preferably 11000 MPa to 26500 MPa at 23° C., as measured in accordance with ISO 178, or a UL94 rating of V0 at a thickness 1.5 mm, or any combinations thereof.

The third polymeric composition can contain a PBT polymer, a filler, and a flame retardant. In some particular aspects, the third polymeric composition can contain 5 wt. % to 80 wt. % of the PBT polymer, 5 wt. % to 35 wt. % of the filler, and 2 wt. % to 20 wt. % the flame retardant. In some aspects, the PBT in the third polymeric composition can be obtained from 1,4-butanediol (BDO) and terephthalic acid. In some particular aspects, 1,4-BDO can be reacted with terephthalic acid and/or a terephthalic acid derivative to produce the PBT polymer. The terephthalic acid derivative, can be obtained from terephthalic acid. The terephthalic acid can be obtained by chemical recycling of PET containing waste. In some aspects, at least a portion of the 1,4 -BDO used to form the PBT can be renewably sourced (e.g., obtained from a bio-renewable source). In some aspects, the bio-renewable source can be tall oil, caster beans, sugar, lignocellulose, or glycerol. The renewably sourced 1,4-BDO can include carbon atoms from the bio-renewable source. In some aspects, the PBT polymer can be a reaction product from polymerizing renewably sourced 1,4-BDO with chemically recycled terephthalic acid. In some aspects, the flame retardant can be a renewably sourced flame retardant. In some particular aspects, the flame retardant can be a non-halogenated flame retardant. The non-halogenated flame retardant can be obtained from bio based chemicals. In some aspects, the filler can contain glass fibers, carbon fibers, or a combination thereof. In some aspects, the carbon fibers can be recycled carbon fibers. In some particular aspects, the filler can contain glass fibers. In certain aspects, the third polymeric composition can further contain an additive selected from pigments, plasticizers, antioxidants, UV-stabilizers, heat stabilizers, dye enhancing agents, lubricant, mold release agents, crystal nucleating agents, fluidability-improving agents, antistatic agents, anti-drip agents, compatibilizers, and/or any combinations thereof. In some particular aspects, the third polymeric composition can contain, 25 wt. % to 60 wt. % of the PBT polymer, 10 wt. % to 35 wt. % of the filler, the filler comprising glass fiber, 5 wt. % to 20 wt. % of the flame retardant, and optionally 0.01 to 3 wt. % of a pigment. In some aspects, the third polymeric composition can have a tensile modulus greater than 5,100 MPa, preferably 10,000 MPa to 12,000 MPa at 23° C., as measured in accordance with ISO 527-2, a tensile strength of at least 70 MPa, preferably 90 MPa to 140 MPa at 23° C. as measured in accordance with ISO 527-2, a heat flexural modulus of greater than 4,500 MPa preferably 7450 MPa to 15000 MPa at 23° C., as measured in accordance with ISO 178, or a UL94 rating of V0 at a thickness 1.5 mm, or any combinations thereof. In some aspects, the at least 90 wt. % of the fan housing can be comprised of the third polymeric composition. In some aspects, the total recycled and renewable content of the second and third polymeric composition containing fan unit can be independently 5 wt. % to 90 wt. %, or 5 wt. % to 60 wt. %. In some aspects, the total recycled and renewable content of the fan unit can be 40 wt. % to 65 wt. %.

Certain aspects of the present invention are directed to a PBT polymer obtained from i) the renewably sourced 1,4-BDO and ii) the chemically recycled terephthalic acid and/or terephthalic acid derivative. The PBT polymer can have the following structure:

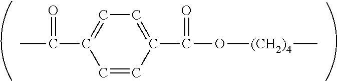

At least 80%, 90%, or 100% of the carbon atoms in the PBT polymer can be from chemically recycled terephthalic acid and/or renewably sourced 1,4-BDO. The renewably sourced 1,4-BDO can be derived from sugar, lignocellulose, and/or glycerol.

In one aspect of the present invention, a resin composition is disclosed that can include 13 wt. % to 20 wt. % mechanically recycled PET, 30 wt. % to 37 wt. % PBT polymer, 28 wt. % to 32 wt. % glass filler, 14 wt. % to 18 wt. % flame retardant, and q.s. to 100 wt. % with additives. In a particular aspect, the resin composition can be defined as illustrated in Table 1 below and having the properties as illustrated in Table 2 below.

Other embodiments of the invention are discussed throughout this application. Any embodiment discussed with respect to one aspect of the invention applies to other aspects of the invention as well and vice versa. Each embodiment described herein is understood to be embodiments of the invention that are applicable to other aspects of the invention. It is contemplated that any embodiment discussed herein can be implemented with respect to any method or composition of the invention, and vice versa. Furthermore, compositions the invention can be used to achieve methods of the invention.

The following includes definitions of various terms and phrases used throughout this specification.

As used herein recycle content of a material refers to wt. % of the material obtained from, made from and/or recovered from waste. Unless mentioned otherwise the waste can be post-industrial and post-consumer waste. Post-consumer waste of a material is a waste generated by a customer of a substrate containing the material. Post-industrial waste is waste generated during a production process of a product and has not used in the consumer market. The recycling can be mechanical and/or chemical recycling processes.

As used herein renewable content of a material refers to wt. % of the material obtained from or made from a bio-based renewable material. Unless mentioned otherwise, bio-based material can include materials from any life form such as plants, animals, fungi, protists, prokaryotes, microbes, algae, bacteria, yeasts and/or moulds. The bio-based material can be obtained from natural or genetically engineered species. Non-limiting examples of bio-based renewable material includes tall oil, caster beans, sugar, lignocellulose, and/or glycerol

As used herein total recycled and renewable content of a material refers to wt. % of the material obtained from, made from and/or recovered from waste and wt. % of the material obtained from or made from a bio-based renewable material. For example, for a 100 gm material if 10 gm is obtained recycled sourced and 10 gm is obtained from renewable source, the total recycled and renewable content of the material is 20 wt. %.

The terms “about” or “approximately” are defined as being close to as understood by one of ordinary skill in the art. In one non-limiting embodiment, the terms are defined to be within 10%, preferably within 5%, more preferably within 1%, and most preferably within 0.5%.

The terms “wt. %,” “vol. %,” or “mol. %” refers to a weight percentage of a component, a volume percentage of a component, or molar percentage of a component, respectively, based on the total weight, the total volume of material, or total moles, that includes the component. In a non-limiting example, 10 grams of component in 100 grams of the material is 10 wt. % of component. The term “ppm” refer to parts per million by weight, based on the total weight, of material that includes the component.

The term “substantially” and its variations are defined to include ranges within 10%, within 5%, within 1%, or within 0.5%.

The terms “inhibiting” or “reducing” or “preventing” or “avoiding” or any variation of these terms, when used in the claims and/or the specification includes any measurable decrease or complete inhibition to achieve a desired result.

The term “effective,” as that term is used in the specification and/or claims, means adequate to accomplish a desired, expected, or intended result.

The use of the words “a” or “an” when used in conjunction with any of the terms “comprising,” “including,” “containing,” or “having” in the claims, or the specification, may mean “one,” but it is also consistent with the meaning of “one or more,” “at least one,” and “one or more than one.”

The phrase “and/or” means and or or. To illustrate, A, B, and/or C includes: A alone, B alone, C alone, a combination of A and B, a combination of A and C, a combination of B and C, or a combination of A, B, and C. In other words, “and/or” operates as an inclusive or.

The words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The polymeric composition and the fan unit of the present invention can “comprise,” “consist(s) essentially of,” or “consist of” particular ingredients, components, compositions, etc. disclosed throughout the specification. In one aspect of the present invention, and with reference to the transitional phrase “consist(s) essentially of” or “consisting essentially of,” a basic and novel characteristic of the present invention can include a fan unit of the present invention having (1) high recycle and renewable content and/or (2) good mechanical properties.

All publications mentioned herein are incorporated herein by reference to disclose and describe the methods and/or materials in connection with which the publications are cited.

Other objects, features and advantages of the present invention will become apparent from the following detailed description and examples. It should be understood, however, that the detailed description and examples, while indicating specific embodiments of the invention, are given by way of illustration only and are not meant to be limiting. Additionally, it is contemplated that changes and modifications within the spirit and scope of the invention will become apparent to those skilled in the art from this detailed description. In further embodiments, features from specific embodiments may be combined with features from other embodiments. For example, features from one embodiment may be combined with features from any of the other embodiments. In further embodiments, additional features may be added to the specific embodiments described herein.

### BRIEF DESCRIPTION OF THE DRAWINGS

Advantages of the present invention may become apparent to those skilled in the art with the benefit of the following detailed description and upon reference to the accompanying drawings. While the invention is susceptible to various modifications and alternative forms, specific embodiments thereof are shown by way of example in the drawings. The drawings may not be to scale.

FIG. 1 illustrates a schematic of various polymer recycling methods.

FIG. 2 schematic of a fan unit according to an example of the present invention.

### DETAILED DESCRIPTION OF THE INVENTION

A discovery has been made that provides a solution to at least some of the problems that may be associated with increasing the sustainability of fan units, such as a fan units of desktop and laptop computers. As illustrated in a non-limiting manner in the Examples, it was found that a composition of the present invention containing particular amounts of mechanically recycled PET polymer, a PBT polymer, a filler, and a flame retardant can provide for compositions with high recycled and/or renewable content and fan units formed with such composition can have good mechanical and acoustic properties. Notably, the high recycle and/or renewable content of the fan units of the present invention can lead to a more sustainable or “green” fan unit without comprising costs and/or mechanical strength of the fan unit.

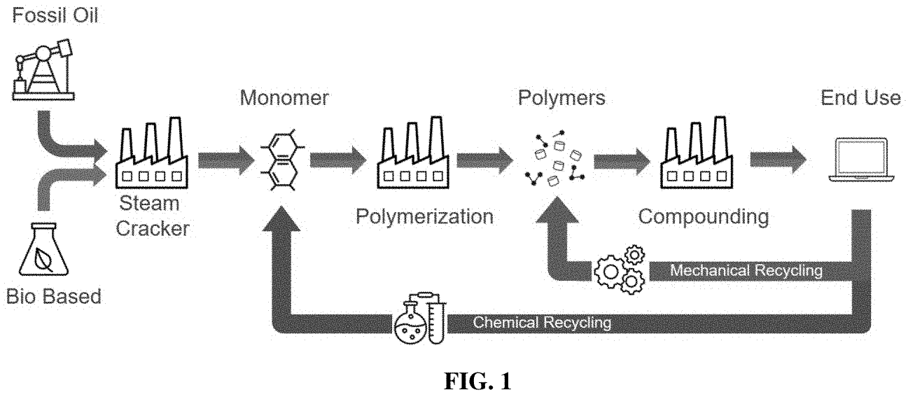

Referring to FIG. 1, a schematic of polymer plastics recycling methods is provided. Polymers (e.g., polyester) derived from fossil oil can be used to form various articles of manufacture (e.g., fan unit of computer), which, after use, can become waste. Polymers are primarily recycled from the waste through mechanical recycling. In mechanical recycling, the waste is recycled through physical processes where the polymer chains are not reduced into monomer units forming the polymer. Rather, mechanical recycling typically includes collecting the waste having the target polymer (e.g., polyester based plastics), optionally washing the waste, melting the waste into a raw material having the target polymer, and reusing the raw material to produce new articles of manufacture. However, the mechanical properties of the mechanically recycled polymer can decrease due to the heat used in melting. The heat can weaken the molecular chains of the polymers. Polymers can also be recycled from waste by chemical recycling. In chemical recycling the polymers from the waste are depolymerized into the monomer units and the monomer units are re-polymerized to form the chemically recycled polymer. Further, polymers formed from bio-based chemicals can be also used to form the articles of manufacture increasing the renewable content of the articles. In certain aspects of the present invention, recycled and renewable content of a fan unit is increased while maintaining the desired mechanical properties of the fan unit by using a chemically recycled and renewably sourced PBT polymer alone or in combination with mechanically recycled PET polymer.

These and other non-limiting aspects of the present invention are discussed in further detail in the following sections.

### A. Polymeric Compositions

In certain aspects, a first polymeric composition of the present invention can contain i) 5 wt. % to 40 wt. %, or at least any one of, equal to any one of, or between any two of 5, 10, 15, 20, 25, 30, 35 and 40 wt. % of a mechanically recycled PET polymer, ii) 5 wt. % to 80 wt. %, or at least any one of, equal to any one of, or between any two of 5, 10, 15, 20, 25, 30, 35, 40, 45, 50, 55, 60, 65, 70, 75, and 80 wt. % of a PBT polymer, iii) 5 wt. % to 40 wt. % or at least any one of, equal to any one of, or between any two of 5, 10, 15, 20, 25, 30, 35 and 40 wt. % of a filler, and iv) 2 wt. % to 20 wt. %, or at least any one of, equal to any one of, or between any two of 2, 4, 6, 8, 10, 12, 14, 16, 18, and 20 wt. % of a flame retardant. The total recycled and renewable content of the first polymeric composition can be 5 wt. % to 90 wt. %, or at least any one of, equal to any one of, or between any two of 5, 10, 15, 20, 25, 30, 35, 40, 45, 50, 55, 60, 65, 70, 75, 80, 85, and 90 wt. %. In some aspects, the first polymeric composition can have a tensile modulus greater than 5,100 MPa, or 5,100 MPa to 12,000 MPa, or 10,000 MPa to 12,000 MPa, or at least any one of, equal to any one of, or between any two of 5100, 6000, 7000, 8000, 9000, 10000, 11000 and 12000 MPa at 23° C., as measured in accordance with ISO 527-2, a tensile strength of at least 70 MPa, or 70 MPa to 140 MPa or, 90 MPa to 140 MPa or at least any one of, equal to any one of, or between any two of 70, 80, 90, 100, 110, 120, 130 and 140 Mpa at 23° C. as measured in accordance with ISO 527-2, a heat flexural modulus of greater than 4,500 MPa, or 4,500 MPa to 10,000 MPa, or 7,450 MPa to 10,000 MPa or at least any one of, equal to any one of, or between any two of 4500, 5000, 6000, 7000, 7450, 8000, 9000, and 10000, MPa at 23° C., as measured in accordance with ISO 178, or a UL94 rating of V0 at a thickness 1.5 mm, or any combinations thereof.

In certain aspects, the second polymeric composition can contain i) 60 wt. % to 95 wt. %, or at least any one of, equal to any one of, or between any two of 60, 65, 70, 75, 80, 85, 90 and 95 wt. % of a LCP, and ii) 5 wt. % to 40 wt. %, or at least any one of, equal to any one of, or between any two of 5, 10, 15, 20, 25, 30, 35 and 40 wt. % of a filler. The LCP polymer at least in part can be a recycled LCP polymer. In some aspects, a portion of the LCP polymer can be virgin polymer. The total recycled and renewable content of the second polymeric composition can be 5 wt. % to 90 wt. %, or at least any one of, equal to any one of, or between any two of 5, 10, 15, 20, 25, 30, 35, 40, 45, 50, 55, 60, 65, 70, 75, 80, 85, and 90 wt. %. In some aspects, the second polymeric composition can have a tensile modulus greater than 12,000 MPa, or 12000 MPa to 23,500 MPa, or 15,000 MPa to 23,500 MPa, or at least any one of, equal to any one of, or between any two of 12000, 13000, 14000, 15000, 16000, 17000, 18000, 19000, 20000, 21000, 22000, 23000, and 23500 MPa at 23° C., as measured in accordance with ISO 527-2, a tensile strength of at least 100 MPa, or 100 MPa to 150 MPa or at least any one of, equal to any one of, or between any two of 100, 110, 120, 130, 140, and 150 MPa at 23° C. as measured in accordance with ISO 527-2, a heat flexural modulus of greater than 10,000 MPa, or 10,000 MPa to 26,500 MPa, or 11,000 MPa to 26,500 MPa, or 12,000 MPa to 26,500 MPa or at least any one of, equal to any one of, or between any two of 10000, 11000, 12000, 13000, 14000, 15000, 16000, 17000, 18000, 19000, 20000, 21000, 22000, 23000, 24000, 25000, 26000, and 26500 MPa at 23° C., as measured in accordance with ISO 178, or a UL94 rating of V0 at a thickness 1.5 mm, or any combinations thereof.

In certain aspects, the third polymeric composition can contain i) 5 wt. % to 80 wt. %, or at least any one of, equal to any one of, or between any two of 5, 10, 15, 20, 25, 30, 35, 40, 45, 50, 55, 60, 65, 70, 75, and 80 wt. % of a PBT polymer, ii) 5 wt. % to 40 wt. %, or at least any one of, equal to any one of, or between any two of 5, 10, 15, 20, 25, 30, 35, and 40 wt. % of a filler, and iii) 2 wt. % to 20 wt. %, or at least any one of, equal to any one of, or between any two of 2, 4, 6, 8, 10, 12, 14, 16, 18, and 20 wt. % of the non-halogenated flame retardant. The total recycled and renewable content of the third polymeric composition can be 5 wt. % to 90 wt. %, or at least any one of, equal to any one of, or between any two of 5, 10, 15, 20, 25, 30, 35, 40, 45, 50, 55, 60, 65, 70, 75, 80, 85, and 90 wt. %. In some aspects, the first polymeric composition can have a tensile modulus greater than 5,100 MPa, or 5,100 MPa to 12,000 MPa, or 10,000 MPa to 12,000 MPa, or at least any one of, equal to any one of, or between any two of 5100, 6000, 7000, 8000, 9000, 10000, 11000, and 12000 MPa at 23° C., as measured in accordance with ISO 527-2, a tensile strength of at least 70 MPa, or 70 MPa to 140 MPa or, 90 MPa to 140 MPa or at least any one of, equal to any one of, or between any two of 70, 80, 90, 100, 110, 120, 130, and 140 MPa at 23° C. as measured in accordance with ISO 527-2, a heat flexural modulus of greater than 4,500 MPa, or 4,500 MPa to 10,000 MPa, or 7,450 MPa to 15,000 MPa or at least any one of, equal to any one of, or between any two of 4500, 5000, 6000, 7000, 7450, 8000, 9000, 10000, 11000, 12000, 12000, 14000 and 15000, MPa at 23° C., as measured in accordance with ISO 178, or a UL94 rating of V0 at a thickness 1.5 mm, or any combinations thereof.

In certain aspects, the first polymeric composition or the third polymeric can independently further contain an additive selected from pigments, plasticizers, antioxidants, UV-stabilizers, heat stabilizers, dye enhancing agents, lubricant, mold release agents, crystal nucleating agents, fluidability-improving agents, antistatic agents, anti-drip agents, compatabilizer, or any combination thereof.

1. Mechanically Recycled PET Polymer

The mechanically recycled PET polymer can be, at least in part, obtained by mechanically recycling of PET containing waste. The mechanically recycled PET polymer can be obtained from the PET containing waste by methods known in the art. Non-limiting examples of PET containing waste includes post-consumer waste, such as plastic bottles waste, textile waste or like, containing PET. In certain aspects, the PET waste can be PET containing Ocean-Bound-Plastic waste. Ocean-Bound-Plastic waste refers to plastic waste that is in risk of ending up in the oceans. The mechanically recycled PET can have a recycle content of at least 85 wt. %, or 85 wt. % to 100 wt. %, or 90 wt. % to 100 wt. %, or 95 wt. % to 100 wt. %, or 98 wt. % to 100 wt. %, or 99 wt. % to 100 wt. %.

2. PBT Polymer

In some aspects, the PBT polymer, can be obtained from a fossil fuel based feed stock. The PBT can be obtained from fossil based feed stocks by methods known in the art. In some aspects, the PBT polymer can be obtained from 1,4-butanediol (BDO) and terephthalic acid. In some particular aspects, 1,4-BDO can be reacted with terephthalic acid and/or a terephthalic acid derivative to produce the PBT polymer. The terephthalic acid derivative, can be obtained from terephthalic acid. Non-limiting examples of the terephthalic acid derivative can include terephalate ester monomers, oligomers and/or polymers. The terephthalic acid (e.g. used directly or indirectly (via terephthalic acid derivative) to form the PBT polymer), at least in part, can be obtained by chemical recycling of PET, from PET containing waste. Non-limiting examples of PET containing waste includes post-consumer waste, such as plastic bottles waste, textile waste or like, containing PET. In certain aspects, the PET waste can be PET containing Ocean-Bound-Plastic waste. PET, from PET containing waste can be depolymerized by methods known in the art to obtain the chemically recycled terephthalic acid. In some aspects, at least a portion of the 1,4 -BDO used to form the PBT can be renewably sourced (e.g., obtained from a bio-renewable source). In some aspects, the bio-renewable source can be tall oil, caster beans, sugar, lignocellulose, or glycerol. The renewably sourced 1,4 -BDO can include carbon atoms from the bio-renewable source. In some aspects, the PBT polymer can be a reaction product from polymerizing renewably sourced 1,4-BDO with chemically recycled terephthalic acid. In some aspects, the PBT polymer obtained from renewably sourced 1,4-butanediol (BDO) and chemically terephthalic acid can have a total recycled and renewable content of at least 90 wt. %, or 90 wt. % to 100 wt. %, or 95 wt. % to 100 wt. %, or 98 wt. % to 100 wt. %, or 99 wt. % to 100 wt. %.

3. Filler

The filler can contain carbon fibers, glass fibers or a combination thereof.

The carbon fibers can at least in part, be post-industrial recycled carbon fibers (e.g., obtained by recycling post-industrial waste). The carbon fibers can be any suitable carbon fibers. The fibers can be sized, unsized, continuous, chopped, seeded, or non-continuous fibers or any combinations thereof. In some aspects, the carbon fibers can be chopped carbon fibers. The sized fibers can be sized with a suitable sizing agents. The fibers can have a suitable length and diameter. The carbon fibers can contain standard modulus, intermediate modulus and/or high modulus carbons. In some aspects, the fibers can be provided in bundles. In certain aspects, the carbon fibers can have average length of 1 to 100 mm, or at least any one of, equal to any one of, or between any two of 1, 10, 20, 30, 40, 50, 60, 70, 80, 90, and 100 mm In certain aspects, the carbon fibers can have average filament diameter of 1 um to 30 um or at least any one of, equal to any one of, or between any two of 1, 5, 10, 15, 20, 25, and 30 um. In certain aspects, the carbon fibers can have a sizing content of 0.5 wt. % to 10 wt. % or at least any one of, equal to any one of, or between any two of 0.5, 1, 2, 3, 4, 5, 6, 7, 8, 9, and 10 wt. %. In certain aspects, the carbon fibers can have a carbon density of 1.5 g/cc to 2 g/cc or 1.75 g/cc to 1.85 g/cc or at least any one of, equal to any one of, or between any two of 1.5, 1.6, 1.7, 1.75, 1.78, 1.8, 1.85, 1.9, 1.95, and 2 g/cc. In some, the carbon fibers have tensile modulus of 30 Msi to 55 Msi or at least any one of, equal to any one of, or between any two of 30, 31, 32, 33, 34, 35, 36, 37, 38, 39, 40, 41,42, 43, 44, 45, 46, 47, 48, 49, 50, 51, 52, 53, 54, and 55 Msi. In some aspects, the carbon fibers can have a recycled content of 10 wt. % to 30 wt. % or at least any one of, equal to any one of, or between any two of 10, 15, 20, 25 and 30 wt. %. Examples of carbon fibers that can be used includes but are not limited to, RE-EV0® HSC commercially available from CARBONCONVERSIONS, RE-EV0® IMC commercially available from CARBONCONVERSIONS, or any combinations thereof.

The glass fibers may include any typical glass fibers known in the art. The fibers can have a suitable length and diameter. The fibers can be long fibers or short fibers that are continuous, chopped, woven, or the like. The short fibers refers to a population of fibers having an average fiber length of less than or equal to 5 mm The long fibers refers to a population of fibers having an average fiber length greater than 5 mm, including for example, a population of fibers having a fiber length in the range of 5 to 20 mm, or 5 to 15 mm The fibers can have a length from 0.2 to 20 mm, or 0.2 to 10 mm, or 0.7 to 7 mm The average diameter of the fibers can be from 1 to 25 micrometers (μm), or 3 to 20 μm, or 4 to 18 μm, or 5 to 17 μm. In some aspects, the glass fibers can include a plurality of chopped glass fibers. The glass fibers may have a circular shape, oval shape, rectangular shape, or dumbbell-like shape having two circles connected to each other in cross-section. The term “glass” refers to a material, natural or synthetic, which contains silicon dioxide (SiO₂) or silica as its main material. The glass fibers can be E, A, C, ECR, R, S, D, and/or NE glass fibers. The glass fibers can be sized or non-sized. The fibers can be sized using any suitable sizing agent. The fibers can be provided in the form of monofilament or multifilament fibers and can be used either alone or in combination with other types of fiber, for example, co-weaving or core/sheath, side-by-side, skin-core type or matrix and fibril constructions, or by other methods including those known to one skilled in the art of fiber manufacture. Exemplary co-woven structures include, for example, glass fiber-carbon or the like. Fibers can be supplied in the form of, for example, bundles, rovings, woven fibrous reinforcements, such as 0-90 degree fabrics or the like; non-woven fibrous reinforcements such as continuous strand mat, chopped strand mat, tissues, papers and felts or the like; or three-dimensional reinforcements such as braids. In some aspects, the glass fibers can be chopped glass fibers.

4. Flame Retardants

In some aspects, the flame retardant can be obtained, at least in part, from a renewable source. In some aspects, the renewable content of the flame retardant can be 30 wt. % to 60 wt. %. In some aspects, the flame retardant can be a non-halogenated flame retardant. In some aspects, the flame retardant can be a non-halogenated phosphorus containing flame retardant obtained from bio-based chemicals. In some aspects, the bio-based chemicals can be tannin, tannic acid, phytic acid, isosorbide, diphenolic acid, deoxyribonucleic acid (DNA), lignin, or β-cyclodextrin or any combination thereof. In some aspects, the flame retardant can contain Bisphenol-A-diphosphate obtained from bio-based chemicals.

### B. Methods for Making the Polymeric Compositions

The polymeric compositions described herein (e.g. first, second or third polymeric compositions) can be made by various methods known in the art such as extrusion, injection molding, compression molding, blow molding, rotational molding, thermoforming, 3-D printing or any combination thereof. For example the components, of the polymeric compositions can be mixed together and then melt-blended to form the composition.

In some aspects, the components of the respective polymeric compositions may be first dry blended with each other, or dry blended with at any suitable combinations, then fed into an extruder from one or multi-feeders, or separately fed into an extruder from one or multi-feeders. The extruders used in the invention may have a single screw, multiple screws, intermeshing co-rotating or counter rotating screws, non-intermeshing co-rotating or counter rotating screws, reciprocating screws, screws with pins, screws with screens, barrels with pins, rolls, rams, helical rotors, co-kneaders, disc-pack processors, various other types of extrusion equipment, or combinations comprising at least one of the foregoing. The extruder can generally be operated at a temperature higher than that necessary to cause the composition to melt and flow. In some aspects, the temperature of the melt in the extruder barrel can be maintained as low as possible in order to avoid excessive thermal degradation of the components. The melted composition exits extruder through small exit holes in a die. The extrudate can be quenched in a water bath and pelletized. The pellets so prepared can be of any desired length (e.g., one-fourth inch long or less). Such pellets can be used for subsequent molding, shaping, or forming.

Mixtures including any combination of the components of the respective polymeric compositions may be subjected to multiple blending and forming steps if desirable. For example, the polymeric composition may first be extruded and formed into pellets. The pellets may then be fed into a molding machine where it may be formed into any desirable shape or product.

### C. Articles of Manufacture

The polymeric compositions (e.g. first, second and/or third polymeric compositions) described herein can be comprised in an article of manufacture. Aspects of the disclosure also relate to articles including the polymeric composition described herein. In some aspects the article can be a film, a sheet, a molded article, a welded article, a filament or a powder. In one example, the composition can be incorporated into a film.

In some aspects, the article can be a computer part. The computer can be desktop computer, laptop computer, notebook computer, cell phone, computer tablet, calculator, computer server or the like. In some particular aspects, the article can be a computer fan unit, such as a desktop computer fan unit or a laptop computer fan unit or a computer server fan unit.

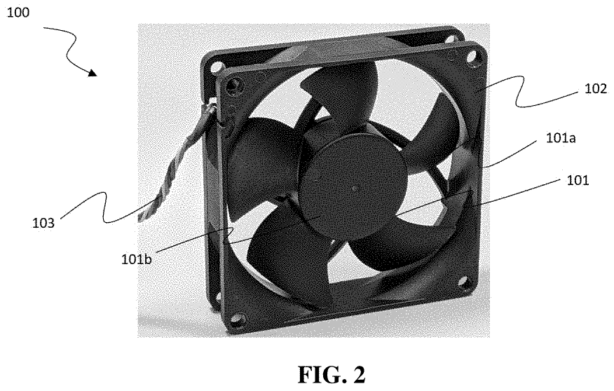

Referring to FIG. 2, a schematic of a fan unit 100 is shown. The fan unit 100 can be a fan unit of a computer or computer server. The fan unit 101 can be configured to be housed inside a casing, and/or chassis of a computer or computer server and can be configured to cool the computer and/or part(s) of the computer or the computer server and/or part(s) of the computer server. The fan unit 100, can contain a fan blade 101 and a fan housing 102. The fan blade 101 can contain one or more blades 101a and a center part 101b connecting the blades 101a. The fan housing 102 can house the fan blade 101 (e.g., the fan housing 102 can function as a casing component for the fan blade 101). The fan unit 100 can also contain a fan motor (not shown) housed in the fan housing 102, and attached directly or indirectly to the fan housing 102. The fan motor can be operationally connected to the fan blade 101, and can be configured to rotate the fan blade 101 with electricity. An electrical wire 103 (attached to at least a portion of the fan unit 100) can be electrically connected to the fan motor and can be configured to supply electricity to the fan motor from an electrical source.

In some aspects, at least 90 wt. %, or at least 95 wt. %, or at least 98 wt. %, or at least 99 wt. %, or about 100 wt. % of the fan blade 101 and the fan housing 102 can be comprised of the first polymeric composition.

In some aspects, at least 90 wt. %, or at least 95 wt. %, or at least 98 wt. %, or at least 99 wt. %, or about 100 wt. % of the fan blade 101 can be comprised of the second polymeric composition, and at least 90 wt. %, or at least 95 wt. %, or at least 98 wt. %, or at least 99 wt. %, or about 100 wt. % of the fan housing 102 can be comprised of the third polymeric composition.

The total recycle and renewable content of the fan unit can be 5 wt. % to 90 wt. %, or 5 wt. % to 80 wt. %, or 5 wt. % to 70 wt. %, or 5 wt. % to 60 wt. %, or at least any one of, equal to any one of, or between any two of 5, 10, 20, 30, 40, 50, 60, 70, 80 and 90 wt. %.

In the context of the present invention, at least the following 27 aspects are described. Aspect 1 is directed to a polymeric composition comprising: 5 wt. % to 30 wt. % of a mechanically recycled polyethylene terephthalate (PET) polymer; 5 wt. % to 80 wt. % of a polybutylene terephthalate (PBT) polymer, wherein the PBT polymer is (i) the reaction product of polymerizing 1,4 butane diol (BDO) with chemically recycled terephthalic acid or is (ii) derived from fossil fuel based feed stock; 5 wt. % to 35 wt. % of a filler; and 2 wt. % to 20 wt. % of a flame retardant. Aspect 2 is directed to the polymeric composition of aspect 1, wherein the polymeric composition is comprised in a fan housing and/or fan blade of a fan unit for an electronic device. Aspect 3 is directed to the polymeric composition of aspect 2, wherein the electronic device is a desktop computer or a laptop computer. Aspect 4 is directed to the polymeric composition of any one of aspects 2 to 3, wherein the fan housing, fan blade, or fan unit, comprises at least 90 wt. % of the polymeric composition. Aspect 5 is directed to the polymeric composition of any one of aspects 1 to 4, wherein the 1,4-BDO is obtained, at least in part, from a bio-renewable source. Aspect 6 is directed to the polymeric composition of aspect 5, wherein the 1,4-BDO bio-renewable source is sugar, lignocellulose and/or glycerol. Aspect 7 is directed to the polymeric composition of any one of aspects 1 to 6, wherein the PBT polymer is the reaction product of polymerizing 1,4 butane diol (BDO) with chemically recycled terephthalic, wherein the chemically recycled terephthalic acid is from polyethylene terephthalate (PET) polymer. Aspect 8 is directed to the polymeric composition of any one of aspects 1 to 7, wherein the polymeric composition has a total recycled and renewable content of 5 wt. % to 60 wt. %. Aspect 9 is directed to the polymeric composition of any one of aspects 1 to 8, comprising a tensile modulus greater than 5,100 MPa, preferably 10,000 MPa to 12,000 MPa at 23° C., as measured in accordance with ISO 527-2, a tensile strength of at least 70 MPa, preferably 90 MPa to 140 MPa at 23° C. as measured in accordance with ISO 527-2, and a heat flexural modulus of greater than 4,500 MPa preferably 7450 MPa to 10000 MPa at 23° C., as measured in accordance with ISO 178, or any combinations thereof. Aspect 10 is directed to the polymeric composition of any one of aspects 1 to 9, wherein the flame retardant is obtained from a renewable source. Aspect 11 is directed to the polymeric composition of any one of aspects 1 to 10, wherein the flame retardant is a non-halogenated phosphorus containing flame retardant obtained from bio based chemicals. Aspect 12 is directed to the polymeric composition of any one of aspects 1 to 11, wherein the filler comprises glass fiber, carbon fiber, or a combination thereof. Aspect 13 is directed to the polymeric composition of any one of aspects 1 to 12, comprising 5 wt. % to 25 wt. % of the PET polymer, 15 wt. % to 40 wt. % of the PBT polymer, 10 wt. % to 35 wt. % of the filler, the filler comprising glass fiber, 5 wt. % to 20 wt. % of the flame retardant, and 0.01 to 3 wt. % of a pigment. Aspect 14 is directed to a fan unit for an electronic device comprising: (a) a fan blade comprising a first polymeric composition comprising: 60 wt. % to 95 wt. % of a liquid crystal polymer (LCP), wherein the LCP is the reaction product of polymerizing an aromatic monomer with a recycled acetic acid and/or a recycled acetic anhydride; and 5 wt. % to 40 wt. % of a first filler; and (b) a fan housing comprising a second polymeric composition comprising: 5 wt. % to 80 wt. % of polybutylene terephthalate (PBT) polymer, wherein the PBT polymer is the reaction product of polymerizing 1,4 butane diol (BDO) with chemically recycled terephthalic acid; 5 wt. % to 35 wt. % of a second filler; and 2 wt. % to 20 wt. % of a non-halogenated flame retardant. Aspect 15 is directed to the fan unit of aspect 14, wherein the fan blade comprises at least 90 wt. % of the first polymeric composition, and wherein the fan housing comprises at least 90 wt. % of the second polymeric composition. Aspect 16 is directed to the fan unit of any one of aspects 14 to 15, wherein the electronic device is a desktop computer or a laptop computer. Aspect 17 is directed to the fan unit of any one of aspects 14 to 16, wherein the first and/or second filler is obtained from a fossil fuel based feed stock and/or a recycled filler. Aspect 18 is directed to the fan unit of any one of aspects 14 to 17, wherein the first and/or second filler comprises independently glass and/or carbon fibers. Aspect 19 is directed to the fan unit of any one of aspects 14 to 18, comprising a total recycled and renewable content of 40 wt. % to 65 wt. %. Aspect 20 is directed to the fan unit of any one of aspects 14 to 19, wherein the 1,4 -BDO is obtained, at least in part, from a bio-renewable source. Aspect 21 is directed to the fan unit of aspect 20, wherein the BDO bio-renewable source is sugar, lignocellulose and/or glycerol. Aspect 22 is directed to the fan unit of any one of aspects 14 to 21, wherein the chemically recycled terephthalic acid is from polyethylene terephthalate (PET). Aspect 23 is directed to the fan unit of any one of aspects 14 to 22, wherein: the first polymeric composition comprises a tensile modulus greater than 12,000 MPa, preferably 15,000 MPa to 23,500 MPa at 23° C., as measured in accordance with ISO 527-2, a Tensile Strength of at least 100 MPa, preferably 150 MPa to 190 MPa at 23° C. as measured in accordance with ISO 527-2, and a heat flexural modulus of greater than 10000 MPa preferably 11000 MPa to 26500 MPa at 23° C., as measured in accordance with ISO 178, or any combinations thereof; and/or the second polymeric composition comprises a tensile modulus greater than 5,100 MPa, preferably 10,000 MPa to 12,000 MPa at 23° C., as measured in accordance with ISO 527-2, a tensile Strength of at least 70 MPa, preferably 90 MPa to 140 MPa at 23° C. as measured in accordance with ISO 527-2, and a heat flexural modulus of greater than 4,500 MPa preferably 7450 MPa to 15000 MPa at 23° C., as measured in accordance with ISO 178, or any combinations thereof. Aspect 24 is directed to a polybutylene terephthalate (PBT) polymer having a structure of:

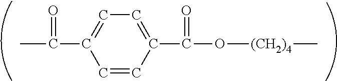

wherein the PBT polymer is the reaction product of polymerizing 1,4 butane diol (BDO) with chemically recycled terephthalic acid. Aspect 25 is directed to the PBT polymer of aspect 24, wherein the BDO comprises carbon atoms from a bio-renewable source. Aspect 26 is directed to the PBT polymer of aspect 25, wherein the bio-renewable source is sugar, lignocellulose and/or glycerol. Aspect 27 is directed to the PBT polymer of any one of aspects 24 to 26, wherein the chemically recycled terephthalic acid is from polyethylene terephthalate (PET).

### EXAMPLES

The present invention will be described in greater detail by way of specific examples. The following examples are offered for illustrative purposes only, and are not intended to limit the invention in any manner Those of skill in the art will readily recognize a variety of noncritical parameters which can be changed or modified to yield essentially the same results.

### Example 1

### Resin Compositions and Fan Units Containing the Resin Compositions

Table 1 provides parameters for non-limiting resin compositions of the present invention.

TABLE 1
Resin composition parameters

| Components | Compositions (wt. %) |
|---|---|
| Mechanically recycled PET | 13 to 20 |
| polymer | |
| PBT polymer | 30 to 37 |
| Glass filler | 28 to 32 |
| Flame retardant | 14 to 18 |
| Additives | 3 to 5 |
| Total | 100 |

The PBT polymer in Table 1 was a reaction product of polymerization of a bio-based 1,4-BDO and a chemically recycled terephthalic acid obtained from chemically recycling PET containing waste. About 40 wt. % of the PBT polymer was obtained from the bio-based 1,4-BDO. The additives in the composition in Table 1 included compatibilizer and colorants.

Compositions having the components in the wt. % ranges in Table 1 were prepared by dry blending and melt extruding the individual components in Table 1 to form molded compositions 1 and 2.

Mechanical properties of molded compositions 1 and 2 are provide in Table 2. Compositions 1 and 2 were tested using the methods outlined in Table 2. It is believed that compositions having the components and wt. % ranges provided in Table 1 will have similar properties to those provided in Table 2.

TABLE 2
Mechanical properties of two compositions

| Properties | Test | Unit | Composition 1 | Composition 2 |
|---|---|---|---|---|
| Melt flow rate | ASTM | g/10 | 12 | 13.5 |
| (275° C./5 Kg) | D 1238 | min | | |
| Specific gravity | ASTM D-792 | g/cm³ | 1.54 | 1.53 |
| Tensile Strength | ASTM D 638 | MPa | 100 | 101 |
| Tensile elongation | ASTM D 638 | % | 4 | 4 |
| at break | | | | |
| Flexural strength | ASTM D 790 | MPa | 150 | 149 |
| Flexural modulus | ASTM D 790 | MPa | 7500 | 7470 |
| Flammability | UL94 | | V0 | V0 |
| at 1.5 mm | | | | |
| thickness | | | | |

Table 2 shows compositions 1 and 2 have good tensile and flexural properties. The compositions have high tensile elongation at break, increasing the ductility and decreasing the brittleness of articles made from the compositions (e.g., fan unit).

Components in the wt. % ranges from the Table 1 composition were dry blended and melt extruded to form pellets containing composition 1 and 2, respectively. The pellets of composition 1 and 2, respectively, were injection molded to form a fan housing and fan blade of computer fan units, fan units 1 and 2 respectively. More than 90 wt. % of the fan housing and fan blade of fan unit 1 was comprised of composition 1. More than 90 wt. % of the fan housing and fan blade of fan unit 2 was comprised of composition 2. FIG. 2 shows the fan unit 2.

### Example 2

### Resin Compositions and Fan Unit Containing the Resin Compositions

Table 3 and 4 provide non-limiting resin compositions of the present invention.

TABLE 3
Composition 3

| Components | Composition 3 (wt. %) |
|---|---|
| PBT polymer | 50 |
| Glass filler | 30 |
| Flame retardant | 16 |
| Additives | 4 |
| Total | 100 |

The PBT polymer of the composition 3 is a reaction product of polymerization of a bio-based 1,4-BDO and a chemically recycled terephthalic acid obtained from chemically recycling PET containing waste. About 36 wt. % of the PBT polymer was obtained from the bio-based 1,4-BDO, and about 74% of the PBT polymer was obtained from the chemically recycled terephthalic acid. The additives in the composition 3 included compatibilizer and colorants and are not believed to affect the mechanical properties of the composition.

TABLE 4
Composition 4

| Components | Composition 4 (wt. %) |
|---|---|
| Recycled LCP polymer | 70 |
| Virgin LCP polymer | 30 |
| Glass filler | 30 |

Components of compositions 3 and 4 were (separately) dry blended and melt extruded to form molded compositions.

Mechanical properties of the molded compositions 3 and 4 was tested using standard methods. Properties of the molded composition 3 and 4 are listed in Table 5.

TABLE 5
Mechanical properties of the compositions 3 and 4

| Properties | Test | Unit | Composition 3 | Composition 4 |
|---|---|---|---|---|
| Tensile Strength | ASTM D 638 | MPa | 105 | 100 |
| Tensile elongation at | ASTM D 638 | % | 1.9 | 1 |
| break | | | | |
| Flexural strength | ASTM D 790 | MPa | 165 | 170 |
| Flexural modulus | ASTM D 790 | MPa | 10,900 | 12,000 |
| Flammability | UL94 | | V0 | V0 |
| at 1.5 mm thickness | | | | |

Components of composition 3 were dry blended and melt extruded to form pellets containing composition 3. The pellets of composition 3 were injection molded to form fan housing of a fan unit, fan unit 3. Components of composition 4 were dry blended and melt extruded to form pellets containing composition 4. The pellets of composition 4 were injection molded to form fan blade of the fan unit 3. More than 90 wt. % of the fan housing of fan unit 3 was comprised of composition 3. More than 90 wt. % of the fan blade of fan unit 3 was comprised of composition 4.

Although embodiments of the present application and their advantages have been described in detail, it should be understood that various changes, substitutions and alterations can be made herein without departing from the spirit and scope of the embodiments as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the above disclosure, processes, machines, manufacture, compositions of matter, means, methods, or steps, presently existing or later to be developed that perform substantially the same function or achieve substantially the same result as the corresponding embodiments described herein can be utilized. Accordingly, the appended claims are intended to include within their scope such processes, machines, manufacture, compositions of matter, means, methods, or steps.

1. A polymeric composition comprising:
5 wt. % to 30 wt. % of a mechanically recycled polyethylene terephthalate (PET) polymer;
5 wt. % to 80 wt. % of a polybutylene terephthalate (PBT) polymer, wherein the PBT polymer is (i) the reaction product of polymerizing 1,4 butane diol (BDO) with chemically recycled terephthalic acid or is (ii) derived from fossil fuel based feed stock;
5 wt. % to 35 wt. % of a filler; and
2 wt. % to 20 wt. % of a flame retardant.

2. The polymeric composition of claim 1, wherein the polymeric composition is comprised in a fan housing and/or fan blade of a fan unit for an electronic device.

3. The polymeric composition of claim 2, wherein the electronic device is a desktop computer or a laptop computer.

4. The polymeric composition of claim 2, wherein the fan housing, fan blade, or fan unit, comprises at least 90 wt. % of the polymeric composition.

5. The polymeric composition of claim 1, wherein the 1,4-BDO is obtained, at least in part, from a bio-renewable source.

6. The polymeric composition of claim 5, wherein the 1,4-BDO bio-renewable source is sugar, lignocellulose and/or glycerol.

7. The polymeric composition of claim 1, wherein the PBT polymer is the reaction product of polymerizing 1,4 butane diol (BDO) with chemically recycled terephthalic, wherein the chemically recycled terephthalic acid is from polyethylene terephthalate (PET) polymer.

8. The polymeric composition of claim 1, wherein the polymeric composition has a total recycled and renewable content of 5 wt. % to 60 wt. %.

9. The polymeric composition of claim 1, comprising a tensile modulus greater than 5,100 MPa, preferably 10,000 MPa to 12,000 MPa at 23° C., as measured in accordance with ISO 527-2, a tensile strength of at least 70 MPa, preferably 90 MPa to 140 MPa at 23° C. as measured in accordance with ISO 527-2, and a heat flexural modulus of greater than 4,500 MPa preferably 7450 MPa to 10000 MPa at 23° C., as measured in accordance with ISO 178, or any combinations thereof.

10. The polymeric composition of claim 1, wherein the flame retardant is obtained from a renewable source.

11. The polymeric composition of claim 1, wherein the flame retardant is a non-halogenated phosphorus containing flame retardant obtained from bio based chemicals.

12. The polymeric composition of claim 1, wherein the filler comprises glass fiber, carbon fiber, or a combination thereof.

13. The polymeric composition of claim 1, comprising 5 wt. % to 25 wt. % of the PET polymer, 15 wt. % to 40 wt. % of the PBT polymer, 10 wt. % to 35 wt. % of the filler, the filler comprising glass fiber, 5 wt. % to 20 wt. % of the flame retardant, and 0.01 to 3 wt. % of a pigment.

14. A fan unit for an electronic device comprising:
(a) a fan blade comprising a first polymeric composition comprising:
60 wt. % to 95 wt. % of a liquid crystal polymer (LCP), wherein the LCP is the reaction product of polymerizing an aromatic monomer with a recycled acetic acid and/or a recycled acetic anhydride; and
5 wt. % to 40 wt. % of a first filler; and
(b) a fan housing comprising a second polymeric composition comprising:
5 wt. % to 80 wt. % of polybutylene terephthalate (PBT) polymer, wherein the PBT polymer is the reaction product of polymerizing 1,4 butane diol (BDO) with chemically recycled terephthalic acid;
5 wt. % to 35 wt. % of a second filler; and
2 wt. % to 20 wt. % of a non-halogenated flame retardant.

15. The fan unit of claim 14, wherein the fan blade comprises at least 90 wt. % of the first polymeric composition, and wherein the fan housing comprises at least 90 wt. % of the second polymeric composition.

16. The fan unit of claim 14, wherein the electronic device is a desktop computer or a laptop computer.

17. The fan unit of claim 14, wherein the first and/or second filler is obtained from a fossil fuel based feed stock and/or a recycled filler.

18. The fan unit of claim 14, wherein the first and/or second filler comprises independently glass and/or carbon fibers.

19. The fan unit of claim 14, comprising a total recycled and renewable content of 40 wt. % to 65 wt. %.

20. The fan unit of claim 14, wherein the 1,4 -BDO is obtained, at least in part, from a bio-renewable source.
